(19) United States
(12) Patent Application Publication
(10) Pub. No.: US 2024/0006286 A1
(43) Pub. Date: Jan. 4, 2024

(54) LAYER SELECTION FOR ROUTING HIGH-SPEED SIGNALS IN SUBSTRATES

(71) Applicant: Intel Corporation, Santa Clara, CA (US)

(72) Inventors: Arghya Sain, Chandler, AZ (US); Sujit Sharan, Chandler, AZ (US); Hoai V. Le, Chandler, AZ (US); Jianyong Xie, Chandler, AZ (US)

(73) Assignee: Intel Corporation, Santa Clara, CA (US)

(21) Appl. No.: 17/856,795

(22) Filed: Jul. 1, 2022

(51) Int. Cl. H01L 23/498; H01L 23/15; H01L 23/00

(52) U.S. Cl. CPC H01L 23/49822; H01L 23/49827; H01L 23/15; H01L 24/16; H01L 2224/16235

(57) ABSTRACT

A substrate comprising a core structure between a first metallization stack and a second metallization stack. A hardware interface is at a side of the second metallization stack. A first interconnect comprises both a first via portion, and a first trace portion which extends from the first via portion in a first routing layer of the first metallization stack. The first via portion extends from the hardware interface, through both the second metallization stack and the core structure, to the first routing layer. A second interconnect comprises both a second via portion, and a second trace portion which extends from the second via portion in the first routing layer. The second via portion extends from the hardware interface, through both the second metallization stack and the core structure, to the first routing layer. A first multi-layer insulator structure adjoins respective sides of the first and second trace portions.

### BACKGROUND

### 1. Technical Field

This disclosure relates generally to semiconductor device packaging, and more specifically, to routing high-speed signals in integrated circuit (IC) device package substrates.

### 2. Background Art

An IC device package may include multiple IC dies and substrates. An IC device package may perform one or more functions requiring high data throughput at high speeds, such as a switching function that employs a serializer/deserializer (SERDES). Switch packages need to support a high data throughput, such as 12.5 TB/s, 25 TB/s, 50 TB/s, or 100 TB/s, or higher. As such, data may need to be transferred over many lanes, e.g., 256 lanes or 512 lanes, at high speeds, e.g., 112 Gb/s or 224 Gb/s, or higher. Each of the lanes includes a transmit differential pair and a receive differential pair, and each differential pair has two conductors. In differential signaling, the signals on each conductor are equal in magnitude but opposite in polarity, and at high signaling speeds, the conductors behave as transmission lines. In addition to the SERDES function, IC device packages may perform other functions that require the transfer of data at high speeds using single-ended or differential signaling. There are a variety of challenges in designing and manufacturing an IC device package that provides high data throughput at high speeds using differential pair traces.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a cross-sectional view of a substrate portion comprising a first metallization stack, a second metallization stack, a core structure between the metallization stacks, and trace portions extending in regions which include a multi-layer insulation structure according to various embodiments;

FIGS. 2A and 2B are cross-sectional views of a region of a substrate comprising a pair of adjacent trace portions according to various embodiments;

FIGS. 3A to 3D are cross-sectional views of regions of a substrate comprising a pair of adjacent trace portions and a single a multi-layer insulation structure adjoining the pair according to various embodiments;

FIGS. 4A and 4B are cross-sectional views of a substrate comprising a pair of adjacent trace portions and a two multi-layer insulation structures adjoining the pair according to various embodiments;

FIG. 5A is a side view of a substrate, FIG. 5B is a plan view of a layer of the substrate, and FIG. 5C is a plan view of traces in a layer of the substrate, according to various embodiments;

FIG. 6 is a functional block diagram of an electronic computing device in accordance with various embodiments; and

FIG. 7 illustrates a mobile computing platform and a data server machine employing an IC device comprising an IC die and a host component, wherein the IC die may include an upper die alignment fiducial and a lower die alignment fiducial, and the host component may include an upper host alignment fiducial and a lower host alignment fiducial in accordance with various embodiments.

### DETAILED DESCRIPTION

Embodiments are directed to selecting layers in a multi-layer substrate for routing high-speed differential signals. Instead of only selecting layers on a first side of a substrate core, embodiments include through-core vias that may be used so that layers on both sides of the core can be used. By selecting routing layers on both sides of the core for routing differential signals, traces may be routed in layers that at least partially adjoin a multi-layer insulator structure. Embodiments may advantageously reduce insertion loss in comparison to substrates that only use layers on one side of a substrate core. In addition, through-core vias with mixed size and pitch, and routing long traces with other than 45-degree angles, where needed, are disclosed.

In some embodiments, one or more single-ended or differential signals are routed on both front and back side layers of a package substrate. Signals that are routed on back side layers using through core vias (TCVs), which meet C4 minimum bump pitch requirements and have dimensions that allow for the signals to be dropped directly to the backside of the package substrate without using front side layers. For high-speed signals (HSIO), embodiments may have the benefit of loss reduction while keeping the layer count constant. But in other instances, the TCVs also allow for signals to be routed more equitably on the package front side and back side layers which can lead to package layer count reduction. Reducing layer count in a package advantageously reduces cost and other manufacturing complexities. Also, the variable size TCVs help with power delivery.

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or functional changes may be made without departing from the scope of claimed subject matter. It should also be noted that directions and references (e.g., up, down, top, bottom, etc.) may be used merely to facilitate the description of features in the drawings and relationship between the features. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with each of the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical, optical, or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example, in the context of materials, one material or structure disposed over or under another may be directly in contact or may have one or more intervening materials. Moreover, one material disposed between two materials may be directly in contact with the two materials or may have one or more intervening materials. In contrast, a first material or structure “on” a second material or structure is in direct contact with that second material/structure. Similar distinctions are to be made in the context of component assemblies where a first component may be “on” or “over” a second component.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

An IC device package substrate can be used to couple two or more IC dies. The substrate may include alternating routing layers and insulator layers, and a core, which serves as a mechanically stable carrier on which the routing and insulator layers can be built. The core of the substrate typically includes a body of an insulator material, and is devoid of patterned routing layers. The substrate itself may be a passive component, which contains metal traces or other shapes, such as ground or power planes, in the routing layers and vias between layers, but typically does not include active devices.

The substrates used to route HS IO (high-speed input/output) signals, e.g., in a serializer/deserializer (SERDES) application, can include a high layer count, e.g., 22 layers, although some substrates may have a more or fewer layers than 22. In addition, the lane count can be high, e.g. 256 to 512 lanes to support the required throughput. Each lane may include two differential pairs. Due to the high lane count, these substrates are second level interconnect (SLI) limited and have form factors in the range of 100 mm×100 mm, although some substrates may have a larger or smaller form factors. (Example SLIs include ball grid arrays and land grid arrays.) Consequently, the HS IO nets in these substrates may have long route lengths (40-50 mm or longer). In addition, many of the routing layers of the substrate can be densely packed with signal traces. Routing layers in the substrate, especially front side routing layers, can have many traces, and the traces in one layer may often overlap vertically with traces in adjacent routing layers directly above or below a particular routing layer.

While some embodiments may be described with reference to particular IC devices that perform a switching function employing a SERDES, it should be appreciated that the principals disclosed herein may be used with other types of IC devices that may also use a SERDES for other purposes in other embodiments. Further, it should be understood that not all embodiments require a SERDES. The principals disclosed herein may be used any suitable type of IC device where there are densely packed with signal traces where signals on some layers need additional separation from other layers.

As mentioned, each lane includes a transmit and receive differential pair, each differential pair has two conductors, and the conductors behave as transmission lines. The conductors are subject to insertion loss. Insertion loss in an IC device substrate is the loss of signal power, measured in decibels (dB), from when the signal enters and to when it leaves a conductive trace. Because insertion loss is proportional to the length of the trace, the long route lengths used to route HS IO signals in substrates makes meeting insertion loss targets difficult.

In differential signaling, the traces may be separated from a ground reference plane by an insulator material. Techniques that increase the distance between differential pair traces and the ground reference plane are useful to reduce insertion loss. However, in a HS IO package, there can be a high density of traces on adjacent route layers. In addition, design rules may limit the number of areas without metal features (so called “voided” or “void” areas) per layer. As a result, techniques to increase the distance between a trace and the ground reference plane may be inefficient or impractical in HS IO packages. For example, due to routing density in adjacent layers, the number of layers in the substrate may need to be increased in order to provide more distance between a pair of traces and a ground plane. However, increasing the number of layers in a substrate already having a high layer count, e.g., 22 layers, is undesirable.

Embodiments are directed to selecting layers in a substrate for routing high-speed differential signals so that one or more traces, and especially longer traces, are routed on layers that at least partially adjoin a multi-layer insulator structure. As explained below, a “multi-layer insulator structure” provides more distance between a pair of traces and a ground plane. In comparison to other routing schemes that provide a multi-layer insulator structure over a segment of a pair of traces, embodiments may increase the length of the segment over which the multi-layer insulator structure is provided or provide more segments that adjoin a multi-layer insulator structure. In addition, more traces may adjoin a multi-layer insulator structure in comparison with other routing schemes that only provide for a limited number of traces that adjoin a multi-layer insulting structure. Advantageously, embodiments may reduce insertion loss for these traces in comparison to other routing schemes. A further advantage is that insertion loss may be reduced without requiring the layer count of the substrate to be increased.

Embodiments provide for selecting layers for routing one or more traces on layers at least partially adjoining a multi-layer insulator structure. These embodiments are made possible by high-density vias for IO signals and IO power rails, with mixed via size and pitch, which allow signals to be routed through the substrate core under the shadow of an IC die attached to the surface of the substrate. For signals and power rails with low current demand, vias having a small size can be used to enable high-density connection for these signals under the shadow of the IC die. For other signals with high current demand, e.g., power rails, vias with large diameters can be used to reduce the resistance, voltage drop, and AC loop inductance.

In some embodiments, the core structure (for brevity, also referred to as a “core” herein) comprises a monolithic body of a core material—such as glass, organic laminates, ceramic, or other suitable materials—which extends continuously between opposite sides of the core structure. In one such embodiment, this “monolithic” core omits any layer of patterned metallization which, for example, might otherwise provide for communication of electrical signals in a horizontal (x-y plane) direction within the core. However, it is not essential that the core omit metallization for horizontal routing of signals in every embodiment. In various embodiments, the core material may have a high elastic modulus and a low coefficient of thermal expansion (CTE). In some embodiments, the core material may be a glass material, which may permit through-core vias may to be formed with a smaller diameter than may be possible with other materials. In some embodiments, the CTE of a glass material used in a core may be higher than the CTE of a standard low CTE core.

In various embodiments, a substrate comprises a core structure, and two metallization stacks which are on opposite sides of the core structure. The term metallization stack” refers herein to an alternating arrangement of first (“routing”) layers—which variously comprise respective patterned metallization structures—and second (“insulator”) layers which variously provide at least some insulation for a given one or more routing layers. In embodiments, the insulator layers can electrically isolate routing layers from each other. The routing and insulator layers can run parallel to each other in a horizontal x-y plane. The metallization structures in the routing layers may comprise any suitable conductive material, e.g., copper. The insulator layers may comprise any suitable nonconductive material, e.g., metal oxides, polymers, organic (e.g., Ajinomoto Build-up Film or ABF®), ceramics, or glasses.

A given interconnect comprises one or more “trace” portions, wherein a given trace portion extends within a routing layer, i.e., in a horizontal (x-y plane) direction.

Additionally or alternatively, a given interconnect of a substrate comprises one or more “via” portions, wherein a given via portion extends to facilitate communication of a signal in a vertical (z-axis) direction through one or more layers of a metallization stack. For example, in some cases, a trace portion of an interconnect extends between, and to each of, two via portions of that same given interconnect. In some embodiments, a given via portion extends vertically through multiple routing and insulator layers (and, for example, through a core of a substrate). Such a via portion—also referred to herein as a “composite via portion” or a “multi-layer via portion”—is comprised of “via sub-portions” (e.g., multiple constituent via portions) which each extend through a different respective layer of the metallization stack.

A given via portion of an interconnect extends through a “via structure” which is formed in a given layer or core—e.g., wherein the via structure comprises a hole which is formed by that layer or core. Unless otherwise indicated, the word “via” on its own—i.e., when not used as part of the term “via portion,” or as part of the term “via structure”—is to be understood as referring herein to a via portion of an interconnect.

In various embodiments, some section of a given trace portion adjoins a structure—referred to herein as a “multi-layer insulation structure” (or “MLIS”)— which is formed by multiple insulator portions (MIPs) of the metallization stack. The multiple insulator portions adjoin each other, and are each in a different respective layer of the stack—e.g., wherein the multiple insulator portions include an insulator portion of an insulator layer, and an insulator portion of neighboring routing layer. For example, at least some section of the trace portion extends in a region which includes the MLIS. In the region, each one of the multiple insulator portions overlaps, or is overlapped by, a respective other one of the multiple insulator portions, wherein the multiple insulators each overlap, or are each overlapped by, that section of the trace portion. In this context, “overlap,” “overlapped” and related terms are with reference to the location of structures each along a line which extends in a vertical (z-axis) dimension. A MLIS may be colloquially referred to in the industry as a “skip layer.” In this nomenclature, the metal portion of a routing layer is said to be “void” or “voided,” as the insulator portion of the routing layer comprises a dielectric material and excludes a metallization feature. A MLIS in a region including a trace portion is useful to reduce losses in the trace portion.

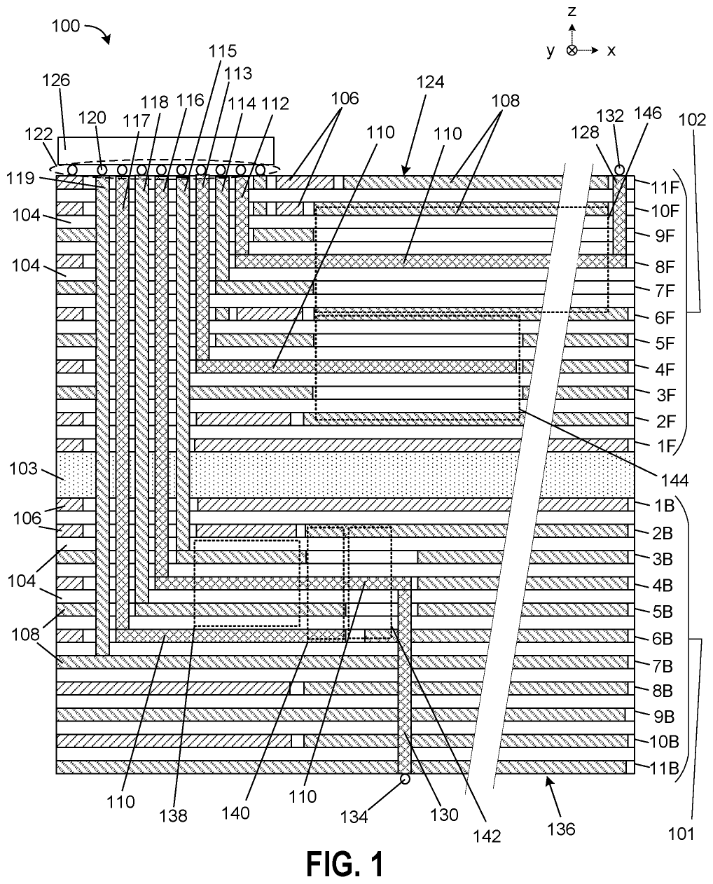

FIG. 1 is a cross-sectional view of a substrate portion 100 comprising a first metallization stack 101, a second metallization stack 102, a core structure 103 between the metallization stacks, and trace portions extending in regions which include a multi-layer insulation structure according to various embodiments. The first metallization stack 101 includes routing layers 1B, 2B, 3B, 4B, 5B, 6B, 7B, 8B, 9B, 10B, and 11B, and an insulator layer 104 between each of these routing layers. The second metallization stack 102 includes routing layers 1F, 2F, 3F, 4F, 5F, 6F, 7F, 8F, 9F, 10F, and 11F, and an insulator layer 104 between each of these routing layers. Routing layers 1B-11B and 1F-11F comprise the following patterned metallization structures: power traces or planes 106, VSS (or ground) traces or planes 108, and trace portions 110 for signals, e.g., HS IO signals. The particular layers in which power shapes 106, VSS shapes 108, and trace portions 110 are routed in FIG. 1 is but one example for illustration purposes only; power shapes 106, VSS shapes 108, and trace portions 110 may be routed in other layers according to the principles described herein in other embodiments. Insulator layer 104 comprises a dielectric material. It should be appreciated that FIG. 1 is not drawn to scale in order to show an example of what may be included in each of the layers. In various embodiments, the width and the depth (in the x-y plane) of substrate portion may be significantly greater than the height in the z-direction. For example, the width and the depth may be 100 mm×100 mm, whereas the height may be less than 10 mm. In addition, power traces or planes 106, VSS traces or planes 108, and trace portions 110 in the respective routing layers may comprise a variety of lengths in the horizontal direction in various embodiments.

A hardware interface 122 is at a first surface 124 of substrate 100 and includes a plurality of contacts 120 for coupling with an IC die 126. In some embodiments, first surface 124 may be a front side of substrate 100. As used herein, the term “hardware interface” refers to one or more physical components of a given device, where said one or more physical components accommodate coupling to interact with one or more physical components of another device. For example, a hardware interface may comprise metal contacts, pads, metallization features, or other interconnect structures on a surface of or within a circuit board or integrated circuit (IC) chip. As a further example, a hardware interface may comprise an interconnect between contacts of respective components, such as solder or an interposer. In an embodiment, contacts 120 may comprise C4 bumps. In an embodiment, IC die 126 comprises serializer circuitry, deserializer circuitry, or serializer/deserializer (SERDES) circuitry. In other embodiments, IC die 126 comprises circuitry for performing other functions that require the transfer of data at high speeds using single-ended or differential signaling. In some embodiments, an active or passive interposer may be substituted for IC die 126, and the interposer may be coupled with an IC die.

Various embodiments are directed to selecting layers in a multi-layer substrate, such as substrate 100, for routing high-speed single-ended or differential signals. Embodiments reduce insertion loss in comparison to some example substrates for routing high-speed differential signals in a substrate. Before further describing FIG. 1, one of these example substrates is reviewed.

An example substrate includes a first metallization stack 101, a second metallization stack 102, and a core structure 103 between the metallization stacks. The example substrate includes trace portions 110 for routing HS IO signals extending only in routing layers 2F, 4F, 6F, and 8F of the second metallization stack 102, while layers 3F, 5F, 7F, and 9F may contain VSS traces or planes 108, or in some cases, power traces or planes 106. The example substrate does not include trace portions 110 in the first metallization stack; all signals are routed in the second metallization stack. In addition, the example substrate includes vias, but the vias do not extend through the substrate core 103. The example substrate is in contrast to the embodiment shown in FIG. 1 where routing layers 2F and 6F are not selected and vias may extend through the substrate core 103 where routing layers 4B and 6B are selected.

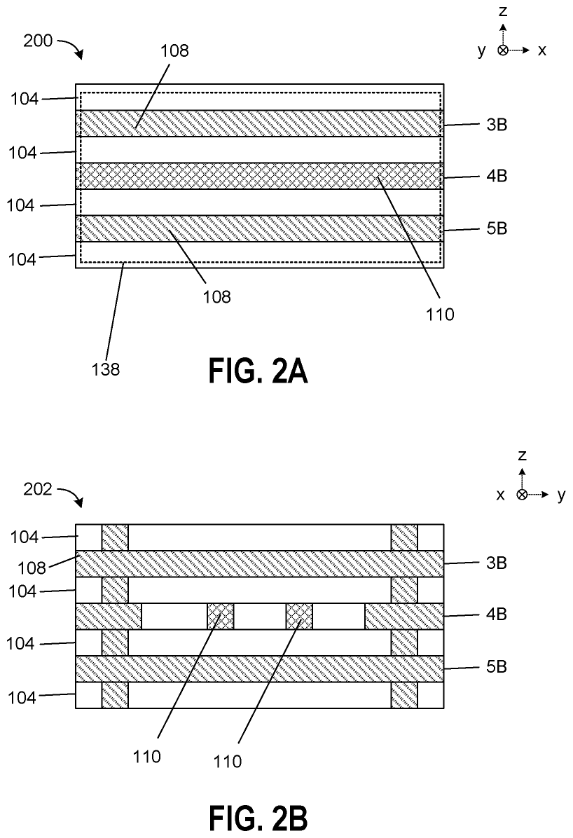

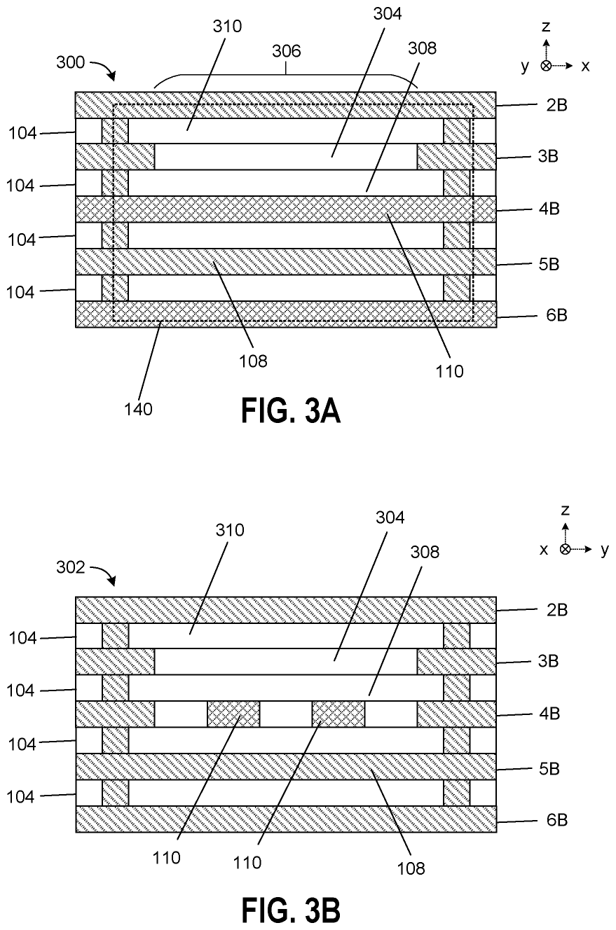

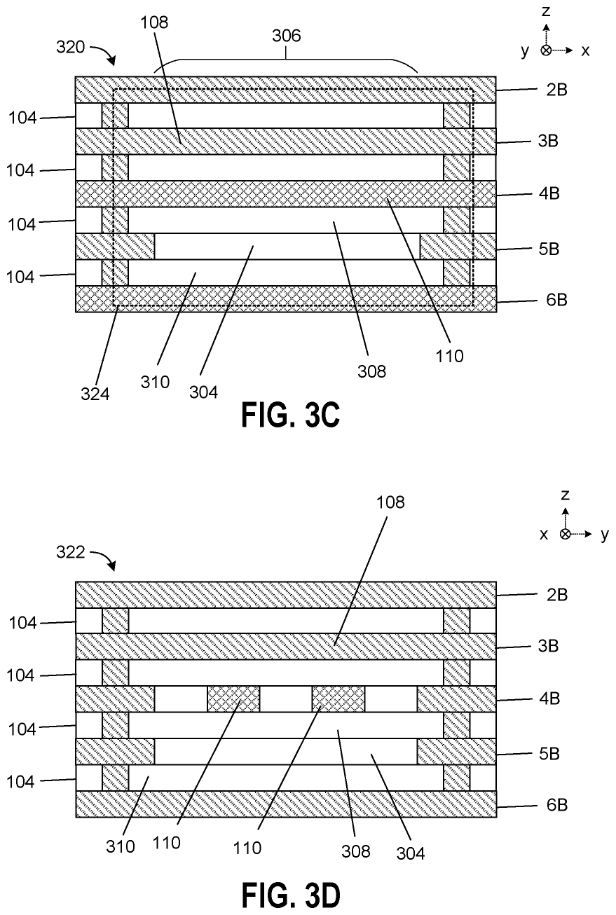

In the example substrate, the top two route layers 8F and 6F typically have the longest trace portions 110, up to 40 mm or longer. Route layers 2F and 4F include trace portions that may be of significant length, but which are shorter than the trace portions in layers 8F and 6F. The topmost route layer 8F may typically include regions of asymmetric skip layer routing with only a small region of symmetric skip layer routing. (See FIGS. 3A-D and 4A-B described below for examples of asymmetric and symmetric skip layer routing.) The routing layer 6F may typically only include asymmetric skip layer routing. The bulk of the routing in the example substrate is either strip line or asymmetric skip layer routing. (See FIGS. 2A-B described below for an example of strip line routing.) The infeasibility of providing a MLIS in regions of trace portions in layers 8F and 6F in the example substrate is described below. The description illustrates that it may be difficult or impractical to provide MLIS in regions above and below trace portions 110 in routing layers 6F and 8F in the example substrate. While only layers 8F and 6F in the example substrate are discussed, it should be appreciated that implementing asymmetric skip layer routing on all layers of the second metallization stack of the example substrate may not be feasible due to layer-to-layer cross talk and routing density in adjacent layers.

First, consider an interconnect of the example substrate that has first, second, and third trace portions 110 in routing layer 8F. The first, second, and third trace portions 110 may together form a relatively long trace as compared with other traces in other layers. The first trace portion may extend horizontally from a via under an IC die attached at or near the center of the substrate. Above the first trace portion in layer 9F, there may be a VSS trace or plane 108. Below the first trace portion in layer 7F, there may be another VSS trace or plane 108. Accordingly, it is not possible to provide a MLIS in a region adjacent to the first trace portion. The second trace portion may extend horizontally from the first trace portion. Layer 9F above the second trace portion is not occupied with a VSS trace or plane 108, but layer 7F below the second trace portion is occupied with a VSS trace 108. Accordingly, it is possible to provide a MLIS in a region above, but not below the second trace portion. The third trace portion may extend horizontally from the second trace portion. Neither layers 9F above or 7F below the third trace portion are occupied with a VSS trace or plane 108. Accordingly, it is possible to provide a MLIS in regions above and below the third trace portion. In summary, in routing layer 8F, the first trace portion may not include an adjacent MLIS, the second trace portion may include a MLIS above it, but not below, and the third trace portion may include a MLIS above and below. In this example, the first and third trace portions may be relatively short, while the second trace portion is relatively long. As the trace portions in routing layer 8F combine to form one of the longest trace portions in the example substrate, it would be desirable to reduce insertion loss by increasing the length of the region where a MLIS may be provided both above and below layer 8F.

Second, consider another interconnect of the example substrate that has fourth and fifth trace portions 110 in routing layer 6F. The fourth and fifth trace portions 110 may together form a relatively long trace as compared with other traces, but not as long as a trace in layer 8F. The fourth trace portion may extend horizontally from a via under an IC die attached at or near the center of the substrate. Above the fourth trace portion in layer 7F, there may be a VSS trace or plane 108. Below the fourth trace portion in layer 5F, there may be another VSS trace or plane 108. Accordingly, it is not possible to provide a MLIS in a region adjacent to the fourth trace portion. The fifth trace portion may extend horizontally from the fourth trace portion. Layer 7F above the fifth trace portion is occupied with a VSS trace or plane 108, but layer 5F below the fifth trace portion is not occupied with a VSS trace or plane 108. Accordingly, it is possible to provide a MLIS in a region below, but not above the fifth trace portion. In summary, in routing layer 6F, the fourth trace portion may not include a MLIS, while the fifth trace portion may include a MLIS below it, but not above. In this example, the fourth trace portion may be relatively long, while the fifth trace portion is a relatively short portion of the combined length. As the trace portions in routing layer 6F combine to form a relatively long trace as compared with other layers, it would be desirable to reduce insertion loss by increasing the length of the region where a MLIS may be provided below layer 6F, and also to provide a region where a MLIS may be provided both above and below layer 6F.

Referring again to the embodiment shown in FIG. 1, it can be seen that only routing layers 4F and 8F of the second metallization stack 102 are selected to contain trace portions 110 for routing HS IO signals. The embodiment illustrated in FIG. 1 is in contrast to the example substrate described above in which routing layers 2F and 6F are selected in addition to layers 4F and 8F for routing HS IO signals. It can also be seen from FIG. 1 that through-core vias extend through core 103 to routing layers 4B and 6B, and trace portions are contained in layers 4B and 6B. The embodiment is in contrast to the example substrate, where only routing layers 2F, 4F, 6F, and 8F of the second metallization stack 102 are selected and vias do not extend through core 103. It should be understood that while trace portions are contained in layers 4B and 6B in FIG. 1, in other embodiments trace portions may be routed in other layers in the first metallization stack, e.g., layers 1B to 3B, 5B, and 7B to 11B.

As may be seen in FIG. 1, the substrate portion 100 includes via portions 112, 114, 116, and 118. In addition, substrate portion 100 may include via portions 128 and 130. Each of the via portions shown in the figure may be one of a pair of via portions for routing a differential pair of traces. Both of the two via portions of a pair are not shown in FIG. 1 because one trace of the pair is adjacent to (behind) the trace show in the figure in a depth y-axis direction. In the following discussion of via portions 112, 114, 116, 118, 128, and 130, the via portions may be referred to in the singular to simplify the explanation. It should be understood, references to a via portion in the singular includes two or more via portions, e.g., two via portions that make up a differential pair of traces.

Via portions 112 and 114 extend through one or more layers of the second metallization stack 102. Via portion 112 extends in a vertical (z-axis) direction and is coupled with a trace 110 in layer 8F and a contact 120 of hardware interface 122. Similarly, via portion 113 is coupled with a trace 110 in layer 4F and a contact 120 of hardware interface 122. Via portion 114 extends in the vertical direction and is coupled with a VSS trace or plane 108 in layer 7F and a contact 120 of hardware interface 122. Similarly, via portion 115 is coupled with a VSS in layer 3F and a contact 120 of hardware interface 122. None of via portions 112, 113, or 114 extend through core 103. The routing of via portions 112, 113, 114, and 115 to particular layers in FIG. 1 is but one example for illustration purposes only; these layers may be routed to other layers according to the principles described herein in other embodiments.

Via portions 116 and 118 extend through one or more layers of both the first and second metallization stacks, 101, 102, and through core 103. Via portion 116 extends in a vertical (z-axis) direction and is coupled with a trace portion 110 in layer 4B and a contact 120 of hardware interface 122. Similarly, via portion 117 is coupled with a trace portion 110 in layer 6B and a contact 120 of hardware interface 122. Via portion 118 extends in the vertical direction and is coupled with a VSS trace or plane 108 in layer 5B and a contact 120 of hardware interface 122. Similarly, via portion 119 is coupled with a VSS in layer 7B and a contact 120 of hardware interface 122. The routing of via portions 116, 117, 118, and 119 to particular layers in FIG. 1 is but one example for illustration purposes only; these layers may be routed to other layers according to the principles described herein in other embodiments.

In various embodiments, the substrate portion 100 includes via portions 128 and 130. Via portion 128 extends in a vertical (z-axis) direction from a contact 132 of a second hardware interface at first surface 124 to one of the trace portions 110 in the second metallization stack 102, e.g. in layer 8F. Via portion 130 extends in a vertical direction from a contact 134 of a third hardware interface at a second surface 136 to one of the trace portions 110 in the first metallization stack 101, e.g. in layer 4B. Second surface 136 is opposite to first surface 124, and in some embodiments, may be a back side of substrate 100. In contrast to via portions 112, 113, 114, 115, 116, 117, 118 and 119, via portions 128 and 130 are not directly below hardware interface 122 or IC die 126. As may be seen in FIG. 1, via portions 128 and 130 are spaced away from the shadow of IC die 126 and, in some embodiments, may be at or near a periphery of substrate 100. In some embodiments, via portions 128 and 130 do not extend through core 103. In other embodiments, one or both of via portions 128 and 130 may extend through core 103. It should be understood that via portions 128 and 130 are but one example for illustration purposes only. In other embodiments, via portions may extend from any of or all of traces in layers 8F, 4F, 6B, and 4B to first surface 124 in a manner similar to via portion 128. In still other embodiments, via portions may extend from any of or all of traces in layers 8F, 4F, 6B, and 4B to second surface 126 in a manner similar to via portion 130. In yet other embodiments, via portions may extend from any desired combination of the traces in layers 8F, 4F, 6B, and 4B to either first surface 124 or second surface 126.

Substrate portion 100 may comprise regions 138, 140, 142, 144, and 146, which are further described with reference to FIGS. 2A, 2B, 3A, 3B, 3C, 4A, and 4B.

FIGS. 2A and 2B are cross-sectional views of a region of a substrate comprising a pair of adjacent trace portions according to various embodiments. FIG. 2A is an enlarged cross-sectional view 200 in the z-x plane, of region 138 of substrate portion 100 of FIG. 1. FIG. 2B is a cross-sectional view 202 of region 138 in the z-y plane. Region 138 is a strip line routing configuration. Routing layer 4B includes two adjacent trace portions 110. Trace portions 110 may be a differential pair. As shown, a pair of routing layers 3B and 5B having.

VSS planes or traces 108 are above and below routing layer 4B. Insulator layers 104 are between trace portions 110 in routing layer 4B and routing layers 3B and 5B. Region 138 does not include a MLIS because the upper insulator layer 104 between layers 3B and 4B, and the lower insulator layer between 4B and 5B, do not adjoin, contact, or lie next to each other. An advantage of embodiments is that regions that do not include a MLIS adjacent to a trace portion, such as region 138, are reduced in length, or are provided on traces of relatively short length, in comparison to other routing schemes, e.g., the example substrate described above.

FIGS. 3A to 3D are cross-sectional views of regions of a substrate comprising a pair of adjacent trace portions and a single a multi-layer insulation structure adjoining the pair according to various embodiments. FIG. 3A is an enlarged cross-sectional view 300, in the z-x plane, of region 140 of substrate portion 100 of FIG. 1. FIG. 3B is a cross-sectional view 302 of region 140 in the z-y plane. Trace portions 110 that extend in region 140 are adjacent to a MLIS. The particular MLIS shown in FIGS. 3A and 3B may be colloquially referred to as an asymmetric skip layer. As shown in FIG. 3B, routing layer 4B includes two adjacent trace portions 110. Below routing layer 4B, routing layer 5B includes a VSS plane 108. Above routing layer 4B, routing layer 3B includes insulator portion 304, extending length 306 and comprising insulating material. As shown in the figures, a first insulator layer 104 is between layers 3B and 4B and includes an insulator portion 308, and a second insulator layer 104 is between layers 2B and 3B includes an insulator portion 310. The insulator portions 308 and 310 each adjoin, contact, and lie next to insulator portion 304. Insulator portions 308 and 310 are each in an insulator layer 104 and insulator portion 304 is in neighboring routing layer 3B. The multiple insulator portions 304, 308, and 310, and portions of traces 110 overlap in the vertical direction along length 306. As such, the portions of traces 110 extending along length 306 are in a region that includes a MLIS above the traces. In some embodiments, trace portions 110 may be wider those shown in FIG. 2, which may advantageously provide lower resistance.

FIG. 3C is a cross-sectional view 320 of a region 324 in the z-x plane. FIG. 3D is a cross-sectional view 322 of the region 324 in the z-y plane. While not depicted in substrate portion 100 of FIG. 1, the substrate portion may include one or more regions 324 in various embodiments. Region 324 is an alternative to region 140, and may be substantially the same as region 140, except that the MLIS is located below instead of above routing layer 4B containing trace portions 110. Traces portions 110 that extend in region 324 are adjacent to a MLIS. Above routing layer 4B, routing layer 3B now includes the VSS plane 108. Below routing layer 4B, routing layer 5B includes now insulator portion 304. The insulator portion 308 is now in a first insulator layer 104 between routing layers 4B and 5B. The insulator portion 310 is now in a second insulator layer 104 between routing layers 5B and 6B.

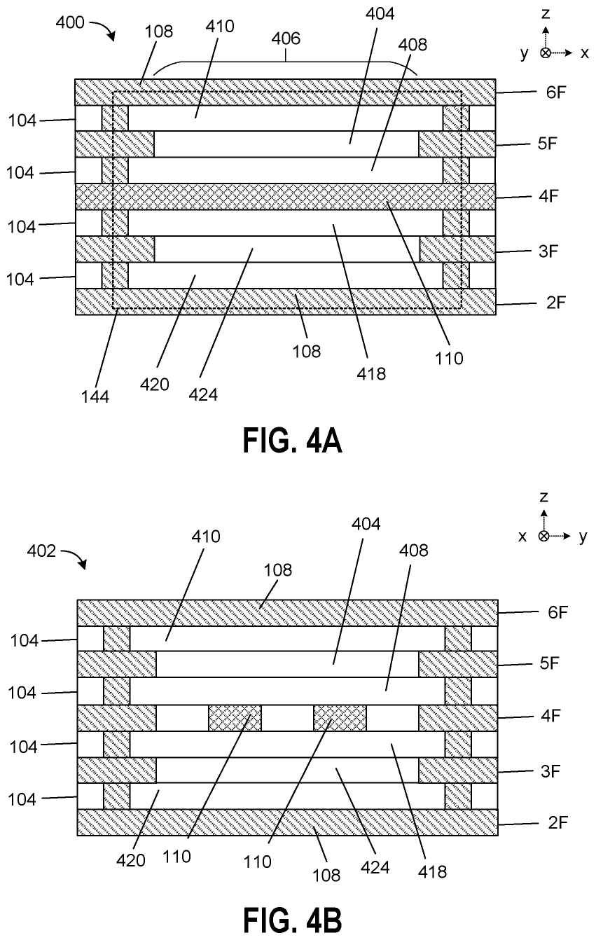

FIGS. 4A and 4B are cross-sectional views of a substrate comprising a pair of adjacent trace portions and a two multi-layer insulation structures adjoining the pair according to various embodiments. FIG. 4A is an enlarged cross-sectional view, in the z-x plane, of region 144 of substrate portion 100 of FIG. 1. FIG. 4B is a cross-sectional view of region 142 in the z-y plane. Regions 144 and 146 are similar to region 142, but may extend different lengths in the x-axis direction and include different routing layers. As shown in FIG. 4B, routing layer 4F includes two adjacent trace portions 110. Trace portions 110 in routing layer 4F overlap in the vertical direction along length 406 with a first MLIS above routing layer 4F and a second MLIS below routing layer 4F. The two MLISs shown in FIGS. 4A and 4B may be colloquially referred to as a symmetric skip layer.

The MLIS above routing layer 4F is first described. Above routing layer 4F, routing layer 6F includes a VSS plane 108. Also, above routing layer 4F, routing layer 5F includes insulator portion 404, extending length 406 and comprising insulating material. A first insulator layer 104 is between layers 4F and 5F and includes an insulator portion 408, and a second insulator layer 104 is between layers 5F and 6F and includes an insulator portion 410. The insulator portions 408 and 410 each adjoin, contact, and lie next to insulator portion 404. Insulator portions 408 and 410 are each in an insulator layer 104 and insulator portion 404 is in neighboring routing layer 5F. The multiple insulator portions 404, 408, and 410, and portions of traces 110 overlap in the vertical direction along length 406. As such, the trace portions 110 extending along length 406 are in a region that includes an MLIS above the traces. In some embodiments, trace portions 110 may be wider those shown in FIG. 2, which may advantageously provide lower resistance.

Turning now to the MLIS below routing layer 4F, routing layer 2F includes a VSS plane 108. In addition, below routing layer 4F, routing layer 3F includes insulator portion 424, extending length 406 and comprising insulating material. A first insulator layer 104 is between layers 3F and 4F and includes an insulator portion 418, and a second insulator layer 104 is between layers 2F and 3F and includes an insulator portion 420. The insulator portions 418 and 420 each adjoin, contact, and lie next to insulator portion 424. Insulator portions 418 and 420 are each in an insulator layer 104 and insulator portion 424 is in neighboring routing layer 3F. The multiple insulator portions 424, 418, and 420, and portions of traces 110 overlap in the vertical direction along length 406. As such, the portions of traces 110 extending along length 406 are in a region that includes a MLIS below the traces

Referring again to FIG. 1, it may be seen that routing layers 8F, 4F in second metallization stack 102, and routing layers 4B and 6B in second metallization stack 101 contain trace portions 110 for routing HS IO signals. In contrast, in the example substrate described above only the second metallization stack is used, wherein routing layers 2F, 4F, 6F, and 8F contain trace portions 110 for routing HS IO signals. A difference between the embodiment shown in FIG. 1 and the example routing scheme is that signals routed on layers 2F and 4F in the example substrate are instead routed on layers 4B and 6B in the embodiment of FIG. 1. This frees up layers 2F and 4F in the second metallization stack. Layer 4F is used for trace portions and layer 2F is used to form a ground plane for the traces in layers 4F. Recall that the example substrate included trace portions 110 in routing layer 6F. The trace portions in layer 6F of the example substrate are moved to layer 4F of the embodiment of FIG. 1, which frees up layer 6F. In the embodiment of FIG. 1, layer 6F is used to form a ground plane for the traces in layers 4F and 8F. The relocation of ground planes to layers 2F and 6F permits MLISs to be formed in layers 3F and 5F in regions adjacent to the traces in layers 4F.

As may be seen in FIG. 1, a trace portion 110 in routing layer 8F is in a region 146 comprising a MLIS above and a MLIS below the trace. This region may extend in a horizontal direction having a length that is longer than may be achievable a trace portion 110 in routing layer 8F in the example routing scheme described above. Similarly, as may be seen in FIG. 1, a trace portion 110 in routing layer 4F is in a region 144 comprising a MLIS above and a MLIS below the trace. This region may extend in a horizontal direction having a length that is longer than may be achievable a trace portion 110 in routing layer 6F in the example routing scheme described above.

By routing the traces on layers 8F and 6F on layers 8F and 4F layers skip layer voids are not required to be shared as is the case with the example substrate. Reducing or eliminating shared skip layer voids results in further reductions in insertion loss.

Still referring to FIG. 1, a first trace portion 110 in routing layer 4B is in a region 142 comprising a MLIS above and a MLIS below the trace. The trace portion in layer 4B is routed in layer 4F in the example substrate. In comparison to the embodiment of FIG. 1, a trace contained in layer 4F of the example substrate may not include region comprising a MLIS above and a MLIS below the trace due to a high density of routing on adjacent layers.

FIG. 1 shows a second trace portion in routing layer 4B is in a region 140 comprising a MLIS above the trace. As mentioned, the trace portion in layer 4B is routed in layer 4F in the example substrate. In comparison to the embodiment of FIG. 1, a trace contained in layer 4F of the example substrate may include a region comprising a MLIS above or below a trace in layer 4F. In some embodiments, however, the length of the region comprising a MLIS above or below a trace in layer 4B may be longer than the region in layer 4F of the example substrate.

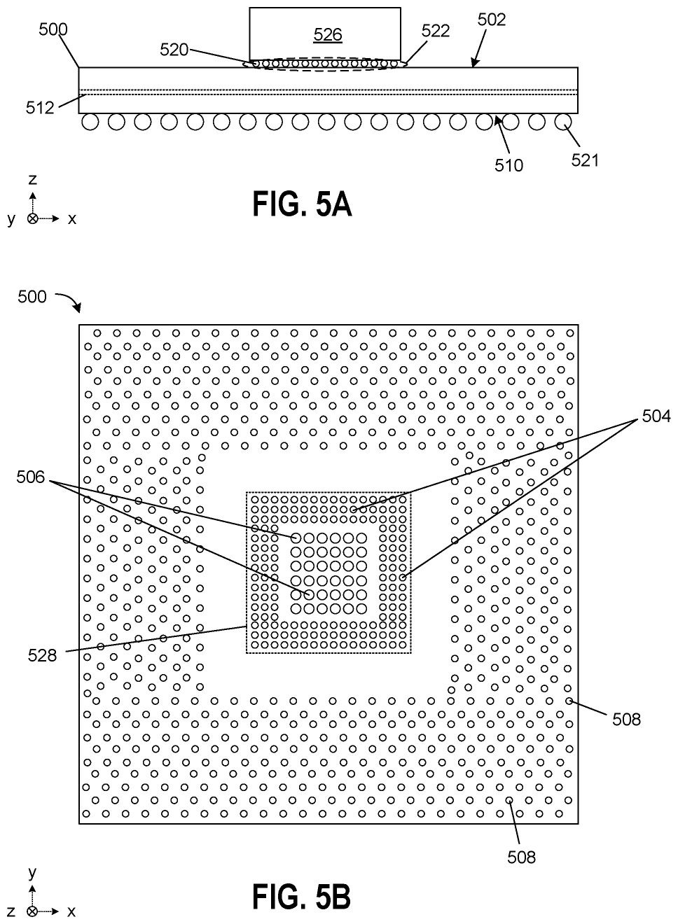

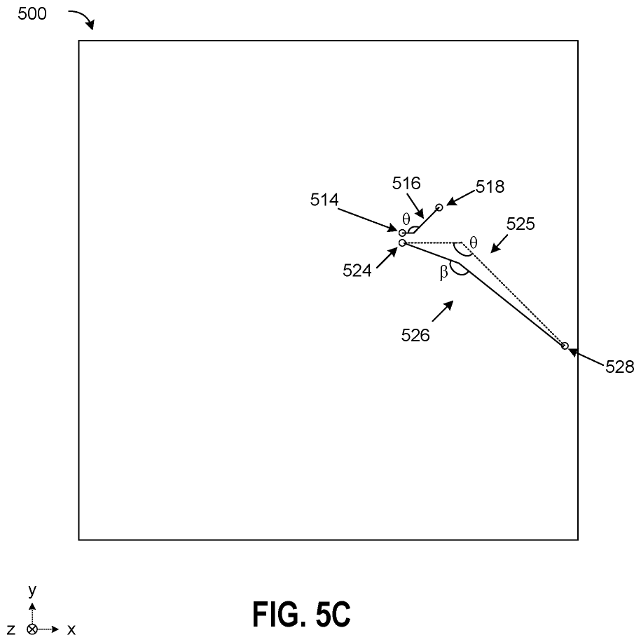

FIG. 5A is a side view of a substrate 500 according to an embodiment. The substrate 500 may be similar to substrate portion 100. An IC die 526 is attached to a first surface 502 of the substrate via contacts 520 of a hardware interface 522. One or more additional IC die may be attached to first surface 502. Substrate 500 includes contacts 521 at a second surface 510 opposite the first surface that may be used to attach substrate 500 to printed circuit board or one or more IC dies. Substrate 500 comprises a first metallization stack, a second metallization stack, and a core structure between the metallization stacks. The core may be at a location indicated by dashed lined 512. The first metallization stack may be between the core and second surface 510. The second metallization stack may be between the core and first surface 502. In an embodiment, IC die 526 comprises a serializer/deserializer (SERDES).

FIG. 5B is a plan view of a layer of the substrate 500, wherein the layer is at or near first surface 502. FIG. 5B shows a location 528 where IC die 526 may be attached, which may be referred to as the die “shadow” of IC die 526. FIG. 5B illustrates a high-density of vias 504 for IO signals or for power delivery, and vias 506 for IO power rails under die shadow 528 according to various embodiments. As described elsewhere in this description, vias 504 and 506 may extend through the core of the substrate 500. The location 528 comprises vias of mixed size and pitch, wherein larger diameter vias 506 are used for power rails for nets with relatively high current density and smaller diameter vias 504 are used for IO signals or power delivery with relatively low current density. In various embodiments, a plurality of the vias 504 and 506 extend straight down from the contacts of the hardware interface 522 through the substrate core to (backside) routing layers, i.e., layers in the first metallization stack. Substrate 500 comprises a plurality of vias 508 outside of and spaced away from die shadow location 528. In embodiments, some vias 508 may be near an edge of substrate 500, while others may be anywhere between the die shadow and edge of the substrate. Vias 508 may be similar to vias 128, 130 shown in FIG. 1. In embodiments, vias may be through-core vias. While the die shadow 528 in the example of FIG. 5B is centered on substrate 500 and has sides that parallel sides of substrate 500, this position for the die shadow is not essential. In embodiments, die shadow 528 may be at any location on substrate 500 with sides placed at any desired orientation with respect to sides of substrate 500.

FIG. 5C is a plan view of traces in a layer of the substrate 500, wherein the layer is a routing layer in one the first or second metallization stack, according to an embodiment. A first trace 516 extends from a via 514 to a via 518. First trace 516 includes an angle θ, which equals 45 degrees. First trace 516 may be a relatively short trace and may comply with a design rule that requires angles in traces be at 45 degrees. In various embodiments, a second trace 526 extends from a via 524 to a via 528. Second trace 526 may be a relatively long trace and includes an angle β, which may be an angle of other than 45 degrees. A routing path 525 between via 524 and via 528 includes an angle θ of 45 degrees. As can be seen by comparing second trace 526 with routing path 525, a long trace, like second trace may be made shorter by forming an angle between segments of the trace at angle β of other than 45 degrees. Insertion loss may be reduced by providing MLIS in regions in layers above or below, or in layers both above and below, the layer in which trace 526 is contained. By shortening the length of trace 526 through the use of angles other than 45 degrees further reduces insertion loss associated with the trace.

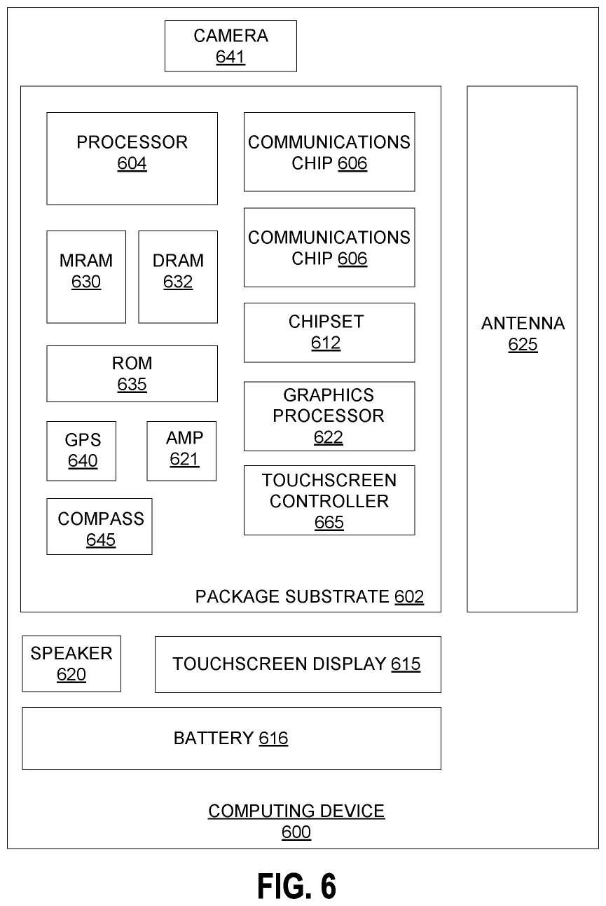

FIG. 6 is a functional block diagram of an electronic computing device 600, in accordance with an embodiment. Device 600 further includes a package substrate 602 hosting a number of components, such as, but not limited to, a processor 604 (e.g., an applications processor). Processor 604 may be physically and/or electrically coupled to package substrate 602. In some examples, processor 604 is within a composite IC chip structure including a chiplet bonded to a host IC chip, for example as described elsewhere herein. Processor 604 may be implemented with circuitry in either or both of the host IC chip and chiplet. In general, the term “processor” or “microprocessor” may refer to any device or portion of a device that processes electronic data from registers and/or memory to transform that electronic data into other electronic data that may be further stored in registers and/or memory.

In various examples, one or more communication chips 606 may also be physically and/or electrically coupled to the package substrate 602. In further implementations, communication chips 606 may be part of processor 604. Depending on its applications, computing device 600 may include other components that may or may not be physically and electrically coupled to package substrate 602. These other components include, but are not limited to, volatile memory (e.g., DRAM 632), non-volatile memory (e.g., ROM 635), flash memory (e.g., NAND or NOR), magnetic memory (MRAM 630), a graphics processor 622, a digital signal processor, a crypto processor, a chipset 612, an antenna 625, touchscreen display 615, touchscreen controller 665, battery 616, audio codec, video codec, power amplifier 621, global positioning system (GPS) device 640, compass 645, accelerometer, gyroscope, speaker 620, camera 641, and mass storage device (such as hard disk drive, solid-state drive (SSD), compact disk (CD), digital versatile disk (DVD), and so forth), or the like. In some exemplary embodiments, computing device 600 includes a substrate comprising a first metallization stack, a second metallization stack, a core structure between the metallization stacks, and trace portions extending in regions which include one or multi-layer insulation structures, for example as described elsewhere herein. For example, one or more of the components 604, 606, 612, 622, 665, 630, 632 635, 643, 621, and 645 may be attached to a substrate substantially similar to substrate portion 100.

Communication chips 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 606 may implement any of a number of wireless standards or protocols. As discussed, computing device 600 may include a plurality of communication chips 606. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

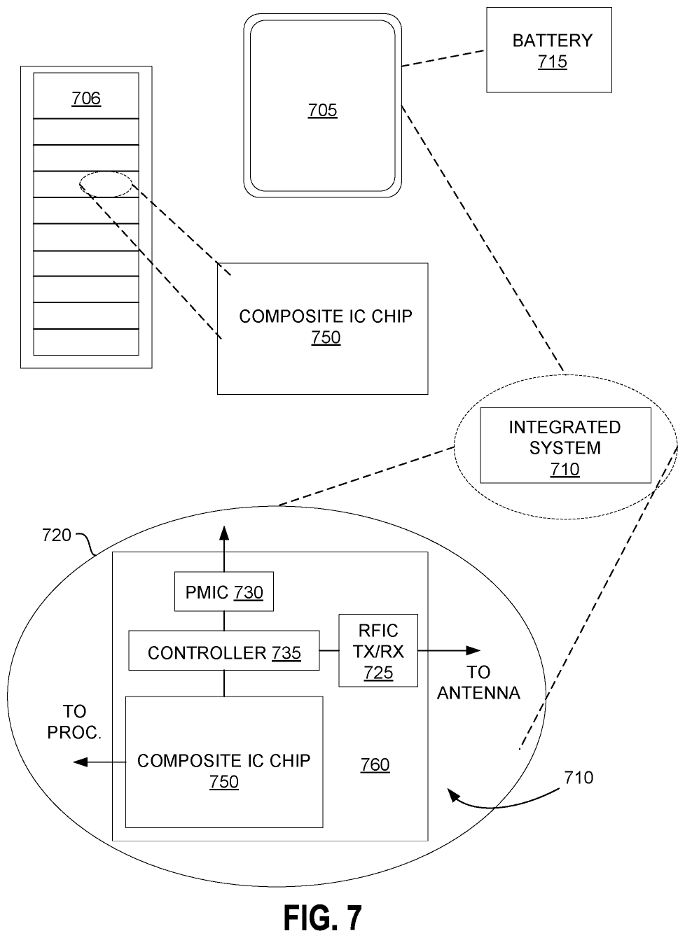

FIG. 7 illustrates a mobile computing platform and a data server machine employing an IC device comprising an IC die and a substrate comprising a first metallization stack, a second metallization stack, a core structure between the metallization stacks, and trace portions extending in regions which include one or multi-layer insulation structures, for example as described elsewhere herein. Computing device 600 may be found inside platform 705 or server machine 706, for example. The server machine 706 may be any commercial server, for example including any number of high-performance computing platforms disposed within a rack and networked together for electronic data processing, which in the exemplary embodiment includes a composite IC chip 750 that includes a chiplet bonded to a host IC chip, for example as described elsewhere herein. The mobile computing platform 705 may be any portable device configured for each of electronic data display, electronic data processing, wireless electronic data transmission, or the like. For example, the mobile computing platform 705 may be any of a tablet, a smart phone, laptop computer, etc., and may include a display screen (e.g., a capacitive, inductive, resistive, or optical touchscreen), a chip-level or package-level integrated system 710, and a battery 715.

Whether disposed within the integrated system 710 illustrated in the expanded view 720, or as a stand-alone package within the server machine 706, composite IC chip 750 may include an IC chip attached to a substrate comprising a first metallization stack, a second metallization stack, a core structure between the metallization stacks, and trace portions extending in regions which include one or multi-layer insulation structures, for example as described elsewhere herein. Composite IC chip 750 may be further coupled to a host substrate 760, along with, one or more of a power management integrated circuit (PMIC) 730, RF (wireless) integrated circuit (RFIC) 725 including a wideband RF (wireless) transmitter and/or receiver (TX/RX) (e.g., including a digital baseband and an analog front end module further comprises a power amplifier on a transmit path and a low noise amplifier on a receive path), and a controller 735. PMIC 730 may perform battery power regulation, DC-to-DC conversion, etc., and so has an input coupled to battery 715 and with an output providing a current supply to other functional modules. As further illustrated, in the exemplary embodiment, RFIC 725 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following examples pertain to further embodiments. Specifics in the examples may be used anywhere in one or more embodiments. All optional features of the apparatus described herein may also be implemented with respect to a method or process. The examples can be combined in any combinations. For example, example 4 can be combined with example 2.

Example 1: A substrate comprising: a first metallization stack; a second metallization stack; a hardware interface at a side of the second metallization stack; a core structure between the first metallization stack and the second metallization stack; wherein a first interconnect of the substrate comprises both a first via portion, and a first trace portion which extends from the first via portion in a first routing layer of the first metallization stack, wherein the first via portion extends from the hardware interface, through both the second metallization stack and the core structure, to the first routing layer; and wherein a second interconnect of the substrate comprises both a second via portion, and a second trace portion which extends from the second via portion in the first routing layer, wherein the second via portion extends from the hardware interface, through both the second metallization stack and the core structure, to the first routing layer.

Example 2: The substrate of example 1, wherein the first metallization stack forms a first multi-layer insulator structure (MLIS) which adjoins respective first sides of the first trace portion and the second trace portion.

Example 3: The substrate of example 2, wherein the first metallization stack further forms a second MLIS which adjoins respective second sides of the first trace portion and the second trace portion.

Example 4: The substrate of any of examples 1 to 3, wherein the core structure comprises a glass material.

Example 5: The substrate of any of examples 1 to 4, wherein the hardware interface is to couple the substrate to an integrated circuit (IC) die, and wherein the first interconnect and the second interconnect are to communicate with the IC die different respective signals of a differential signal pair.

Example 6: The substrate of example 5, wherein the IC die comprises at least one of serializer circuitry or deserializer circuitry.

Example 7: The substrate of any of examples 1 to 5, wherein a third interconnect of the substrate comprises both a third via portion, and a third trace portion which extends from the third via portion in a second routing layer of the second metallization stack, wherein the third via portion extends from the hardware interface to the third routing layer; wherein a fourth interconnect of the substrate comprises both a fourth via portion, and a fourth trace portion which extends from the fourth via portion in the second routing layer, wherein the fourth via portion extends from the hardware interface to the fourth routing layer; and wherein the second metallization stack forms a second MLIS which adjoins respective second sides of the third trace portion and the fourth trace portion.

Example 8: The substrate of example 7, wherein the second metallization stack further forms a third MLIS which adjoins respective third sides of the third trace portion and the fourth trace portion.

Example 9: The substrate of example 7, wherein a length of the third trace portion in the second routing layer is greater than a length of the first trace portion in the first routing layer.

Example 10: The substrate of example 7, wherein the hardware interface is to couple the substrate to an integrated circuit (IC) die, and wherein the third interconnect and the fourth interconnect are to communicate with the IC die different respective signals of a differential signal pair.

Example 11: The substrate of any of examples 1 to 7, wherein: the hardware interface is a first hardware interface; the substrate further comprises a second hardware interface at the side of the second metallization stack; the first interconnect further comprises a third via portion which extends to the second hardware interface; the second interconnect further comprises a fourth via portion which extends to the second hardware interface.

Example 12: The substrate of example 11, wherein: the third via portion extends from the second hardware interface, through both the second metallization stack and the core structure, to the first trace portion in the first routing layer; or the fourth via portion extends from the second hardware interface, through both the second metallization stack and the core structure, to the second trace portion in the first routing layer.

Example 13: The substrate of any of examples 1 to 7, wherein: the hardware interface is a first hardware interface; the substrate further comprises a second hardware interface at another side of the first metallization stack; the first interconnect further comprises a third via portion which extends to the second hardware interface; and the second interconnect further comprises a fourth via portion which extends to the second hardware interface.

Example 14: The substrate of any of examples 1 to 7, wherein the first via portion and the second via portion each extend to the first routing layer in a direction substantially orthogonal to the side.

Example 15: The substrate of any of examples 1 to 7, wherein the first trace portion includes an angle measuring other than 45 degrees.

Example 16: An IC device, comprising: a substrate comprising: a core structure between a first metallization stack and a second metallization stack, wherein each of the first metallization stack and second metallization stack comprise a plurality of routing layers separated by a plurality of dielectric layers; a hardware interface at a side of the second metallization stack; a first interconnect comprising a first via portion, and a first trace portion which extends from the first via portion in a first routing layer of the first metallization stack, wherein the first via portion extends from the hardware interface, through both the second metallization stack and the core structure, to the first routing layer; a second interconnect comprising a second via portion, and a second trace portion which extends from the second via portion in the first routing layer, wherein the second via portion extends from the hardware interface, through both the second metallization stack and the core structure, to the first routing layer; and an integrated circuit (IC) die coupled with the hardware interface.

Example 17: The IC device of example 16, wherein the core structure comprises a glass material.

Example 18: The IC device of example 16 or example 17, wherein the substrate further comprises: a third interconnect comprising a third via portion, and a third trace portion which extends from the third via portion in a second routing layer of the second metallization stack, wherein the third via portion extends from the hardware interface to the third routing layer; a fourth interconnect comprising both a fourth via portion, and a fourth trace portion which extends from the fourth via portion in the second routing layer, wherein the fourth via portion extends from the hardware interface to the fourth routing layer; and wherein the second metallization stack forms a second MLIS which adjoins respective second sides of the third trace portion and the fourth trace portion.

Example 19: A system comprising: a system board and a power supply coupled with the system board; an integrated circuit (IC) device coupled with the system board and to receive power from the power supply, the IC device; and a substrate coupled with the IC device, the substrate comprising: a core structure between a first metallization stack and a second metallization stack; a hardware interface at a side of the second metallization stack; a first interconnect comprising a first via portion, and a first trace portion which extends from the first via portion in a first routing layer of the first metallization stack, wherein the first via portion extends from the hardware interface, through both the second metallization stack and the core structure, to the first routing layer; and a second interconnect comprising a second via portion, and a second trace portion which extends from the second via portion in the first routing layer, wherein the second via portion extends from the hardware interface, through both the second metallization stack and the core structure, to the first routing layer.

Example 20: The system of example 19, wherein the first metallization stack forms a first multi-layer insulator structure (MLIS) which adjoins respective first sides of the first trace portion and the second trace portion and a second MLIS which adjoins respective second sides of the first trace portion and the second trace portion, and wherein the hardware interface is to couple the substrate to the IC die, and wherein the first interconnect and the second interconnect are to communicate with the IC die different respective single-ended signals.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should therefore be determined with reference to the appended claims, along with the full scope of equivalents to which such claims are entitled.

What is claimed is:

1. A substrate comprising:
a first metallization stack;
a second metallization stack;
a hardware interface at a side of the second metallization stack;
a core structure between the first metallization stack and the second metallization stack;
wherein a first interconnect of the substrate comprises both a first via portion, and a first trace portion which extends from the first via portion in a first routing layer of the first metallization stack, wherein the first via portion extends from the hardware interface, through both the second metallization stack and the core structure, to the first routing layer; and
wherein a second interconnect of the substrate comprises both a second via portion, and a second trace portion which extends from the second via portion in the first routing layer, wherein the second via portion extends from the hardware interface, through both the second metallization stack and the core structure, to the first routing layer.

2. The substrate of claim 1, wherein the first metallization stack forms a first multi-layer insulator structure (MLIS) which adjoins respective first sides of the first trace portion and the second trace portion.

3. The substrate of claim 2, wherein the first metallization stack further forms a second MLIS which adjoins respective second sides of the first trace portion and the second trace portion.

4. The substrate of claim 1, wherein the core structure comprises a glass material.

5. The substrate of claim 1, wherein the hardware interface is to couple the substrate to an integrated circuit (IC) die, and wherein the first interconnect and the second interconnect are to communicate with the IC die different respective signals of a differential signal pair.

6. The substrate of claim 5, wherein the IC die comprises at least one of serializer circuitry or deserializer circuitry.

7. The substrate of claim 1, wherein a third interconnect of the substrate comprises both a third via portion, and a third trace portion which extends from the third via portion in a second routing layer of the second metallization stack, wherein the third via portion extends from the hardware interface to the third routing layer;
wherein a fourth interconnect of the substrate comprises both a fourth via portion, and a fourth trace portion which extends from the fourth via portion in the second routing layer, wherein the fourth via portion extends from the hardware interface to the fourth routing layer; and
wherein the second metallization stack forms a second MLIS which adjoins respective second sides of the third trace portion and the fourth trace portion.

8. The substrate of claim 7, wherein the second metallization stack further forms a third MLIS which adjoins respective third sides of the third trace portion and the fourth trace portion.

9. The substrate of claim 7, wherein a length of the third trace portion in the second routing layer is greater than a length of the first trace portion in the first routing layer.

10. The substrate of claim 7, wherein the hardware interface is to couple the substrate to an integrated circuit (IC) die, and wherein the third interconnect and the fourth interconnect are to communicate with the IC die different respective signals of a differential signal pair.

11. The substrate of claim 1, wherein:
the hardware interface is a first hardware interface;
the substrate further comprises a second hardware interface at the side of the second metallization stack;
the first interconnect further comprises a third via portion which extends to the second hardware interface;
the second interconnect further comprises a fourth via portion which extends to the second hardware interface.

12. The substrate of claim 11, wherein:
the third via portion extends from the second hardware interface, through both the second metallization stack and the core structure, to the first trace portion in the first routing layer; or
the fourth via portion extends from the second hardware interface, through both the second metallization stack and the core structure, to the second trace portion in the first routing layer.

13. The substrate of claim 1, wherein:
the hardware interface is a first hardware interface;
the substrate further comprises a second hardware interface at another side of the first metallization stack;
the first interconnect further comprises a third via portion which extends to the second hardware interface; and
the second interconnect further comprises a fourth via portion which extends to the second hardware interface.

14. The substrate of claim 1, wherein the first via portion and the second via portion each extend to the first routing layer in a direction substantially orthogonal to the side.

15. The substrate of claim 1, wherein the first trace portion includes an angle measuring other than 45 degrees.

16. An IC device, comprising:
a substrate comprising:
a core structure between a first metallization stack and a second metallization stack, wherein each of the first metallization stack and second metallization stack comprise a plurality of routing layers separated by a plurality of dielectric layers;
a hardware interface at a side of the second metallization stack;
a first interconnect comprising a first via portion, and a first trace portion which extends from the first via portion in a first routing layer of the first metallization stack, wherein the first via portion extends from the hardware interface, through both the second metallization stack and the core structure, to the first routing layer;
a second interconnect comprising a second via portion, and a second trace portion which extends from the second via portion in the first routing layer, wherein the second via portion extends from the hardware interface, through both the second metallization stack and the core structure, to the first routing layer; and
an integrated circuit (IC) die coupled with the hardware interface.

17. The IC device of claim 16, wherein the core structure comprises a glass material

18. The IC device of claim 16, wherein the substrate further comprises:
a third interconnect comprising a third via portion, and a third trace portion which extends from the third via portion in a second routing layer of the second metallization stack, wherein the third via portion extends from the hardware interface to the third routing layer;
a fourth interconnect comprising both a fourth via portion, and a fourth trace portion which extends from the fourth via portion in the second routing layer, wherein the fourth via portion extends from the hardware interface to the fourth routing layer; and
wherein the second metallization stack forms a second MLIS which adjoins respective second sides of the third trace portion and the fourth trace portion.

19. A system comprising:
a system board and a power supply coupled with the system board;
an integrated circuit (IC) device coupled with the system board and to receive power from the power supply, the IC device; and
a substrate coupled with the IC device, the substrate comprising:
a core structure between a first metallization stack and a second metallization stack;
a hardware interface at a side of the second metallization stack;
a first interconnect comprising a first via portion, and a first trace portion which extends from the first via portion in a first routing layer of the first metallization stack, wherein the first via portion extends from the hardware interface, through both the second metallization stack and the core structure, to the first routing layer; and
a second interconnect comprising a second via portion, and a second trace portion which extends from the second via portion in the first routing layer, wherein the second via portion extends from the hardware interface, through both the second metallization stack and the core structure, to the first routing layer.

20. The system of claim 19, wherein the first metallization stack forms a first multi-layer insulator structure (MLIS) which adjoins respective first sides of the first trace portion and the second trace portion and a second MLIS which adjoins respective second sides of the first trace portion and the second trace portion, and wherein the hardware interface is to couple the substrate to the IC die, and wherein the first interconnect and the second interconnect are to communicate with the IC die different respective single-ended signals.
